(19) United States
(12) Patent Application Publication
(10) Pub. No.: US 2019/0371652 A1
(43) Pub. Date: Dec. 5, 2019

(54) INTEGRATED CIRCUIT CHIP PACKAGE HAVING REDUCED CONTACT PAD SIZE

(71) Applicant: QUALCOMM Incorporated, San Diego, CA (US)

(72) Inventors: Hong Bok WE, San Diego, CA (US); Chin-Kwan KIM, San Diego, CA (US); Jaehyun YEON, San Diego, CA (US); Kuiwon KANG, San Diego, CA (US)

(21) Appl. No.: 15/996,549

(22) Filed: Jun. 4, 2018

(51) Int. Cl. H01L 21/768; H01L 23/522; H01L 23/528; H01L 23/532; H01L 21/02

(52) U.S. Cl. CPC H01L 21/76805; H01L 23/5226; H01L 23/5283; H01L 23/53228; H01L 21/02063; H01L 21/76816; H01L 21/76874; H01L 21/76879; H01L 21/76814

(57) ABSTRACT

An interconnect comprises a dielectric, a via formed in the substrate having a first diameter and a second diameter, and a contact pad for aligning the via on the substrate along the second diameter, wherein the contact pad has a width smaller than the second diameter. The contact pad may be line-shaped. The second diameter is approximately 2×-10× bigger than the contact pad width. The contact pad width is approximately 2-15 microns, and the first diameter is approximately 10-60 microns. The substrate may be used for routing input/output signals and design. The via may be performed using photolithography, laser ablation, and/or plasma etching.

### BACKGROUND

### Field

Aspects of the disclosure relate to semiconductor devices and, more specifically, to apparatus and method of fabricating a multiple-layer, interconnected integrated circuit chip package having reduced contact pad size.

### Background

Multiple-layer, interconnected chip packages are used to provide signal paths, power distribution paths, and interconnections between locations on an integrated circuit (IC) chip package. The use of multiple layers facilitates an increase in the density of the IC which can be mounted on top of a substrate because it allows signal and power lines to be placed on layers other than the layer on which the IC is mounted. One way to interconnect the different substrates to enable signals and power to be routed between IC pins and connections on the package is by forming a through hole that extends vertically through aligned regions on different substrate layers. The through hole is typically formed by a mechanical or laser drill, or plasma etching, with the hole being plated to provide a conductive interconnection between the layers. An example of the conductive interconnection is a via connection. The conventional method, however, requires large contact pads for the conductive or via interconnections between the layers. In particular, the large contact pads currently take up more than 30% of the substrate that could be used for routing of input/output (I/O) signals and design. Accordingly, there is a need for an apparatus and method of fabricating a multi-layer interconnected integrated circuit chip package or structure having reduced contact pad size.

### SUMMARY

The following presents a simplified summary of one or more aspects to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

An interconnect structure is described. The interconnect structure comprises a dielectric; a via formed in the dielectric having a first diameter and a second diameter; and a contact pad aligned with the second diameter of the via, wherein the contact pad has a width smaller than the second diameter. The contact pad may be line-shaped. The second diameter, e.g., is approximately 2 to 10 times bigger than the contact pad width. The contact pad width, e.g., is approximately 2-15 microns, and the first diameter, e.g., is approximately 10-60 microns. The dielectric may be used for routing input/output signals and design. The via may be formed using photolithography, laser ablation, and/or plasma etching.

A method of fabricating an interconnect structure is described. The method comprises providing a contact pad; forming a dielectric over the contact pad; forming a via opening in the dielectric, the via having a first diameter and a second diameter; performing seed copper (Cu) deposition of the via opening to form a seed Cu layer; performing copper (Cu) patterning using photolithography over the seed Cu layer; removing the seed copper Cu layer, wherein the contact pad has a width smaller than the second diameter. Providing the contact pad may include opening the dielectric to expose the contact pad. Opening the dielectric may be done by photolithography, laser ablation, and/or plasma etching. Forming the dielectric may be by lamination, coating, and/or pressing above the contact pad. Forming the via opening may be, for example, by an exposure process, laser ablation by carbon dioxide (CO₂), gas laser beam, ultraviolet (UV) laser beam, and/or excimer laser beam. The method may further comprise plasma cleaning or vapor honing of via opening walls. The opened via and dielectric may then be covered by a seed layer, after which a photoresist may then be applied and developed in a patterning-exposure process. After the photoresist is developed, the opened via and pattern area may be filled by copper (Cu) plating on the seed layer.

These and other aspects of the invention will become more fully understood upon a review of the detailed description, which follows. Other aspects of the invention will become apparent to those of ordinary skill in the art, upon reviewing the following description of specific, exemplary aspects of the invention in conjunction with the accompanying figures.

### BRIEF DESCRIPTION OF THE DRAWINGS

FIGS. 1A & 1B are side cross-sectional and top views, respectively, illustrating a conventional interconnection structure of the prior art;

FIGS. 2A & 2B, are side cross-sectional and top views, respectively, illustrating an interconnection structure according to one aspect of the invention; and

FIGS. 3A-3F illustrate a method of fabricating an interconnection structure according to one aspect of the invention.

### DETAILED DESCRIPTION

The detailed description set forth below, in connection with the appended drawings, is intended as a description of exemplary aspects and is not intended to represent the only aspects in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

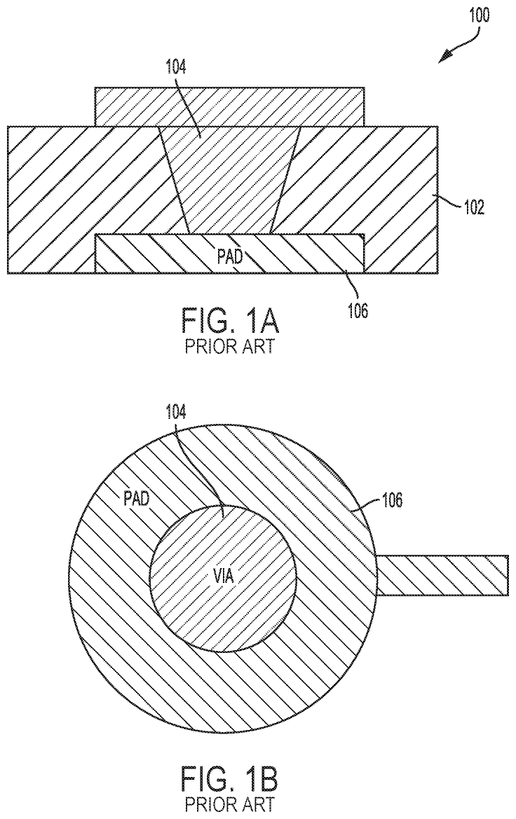

FIG. 1A is a side cross-sectional view illustrating a conventional interconnection structure 100 of the prior art. Interconnection structure 100 includes a dielectric 102, a via 104, and a contact pad 106 of the dielectric 102. The contact pad 106 is a ring- or donut-shaped pad as shown in FIG. 1B, and formed from a conductive material. The via 104 has a diameter of approximately 60 microns, and the contact pad 106 has a diameter of approximately 120 microns. In particular, the diameter of the contact pad 106 is approximately 2 times the diameter of the via 104 and, as a result, the contact pad 106 currently takes up more than 30% of the dielectric 102 that could be used for routing of input/output (I/O) signals and design. The contact pad 106 is formed using photolithography and plating techniques in locations on the dielectric 102. For example, a controlled laser may be used to drill the via 104 and stop at the contact pad 106 of the dielectric 102. A plasma based process may also be used to drill the via 104. The via 104 may then be cleaned with a wet chemical or plasma etch process to remove any residue. The laser drilling forms a via extending through the dielectric 102.

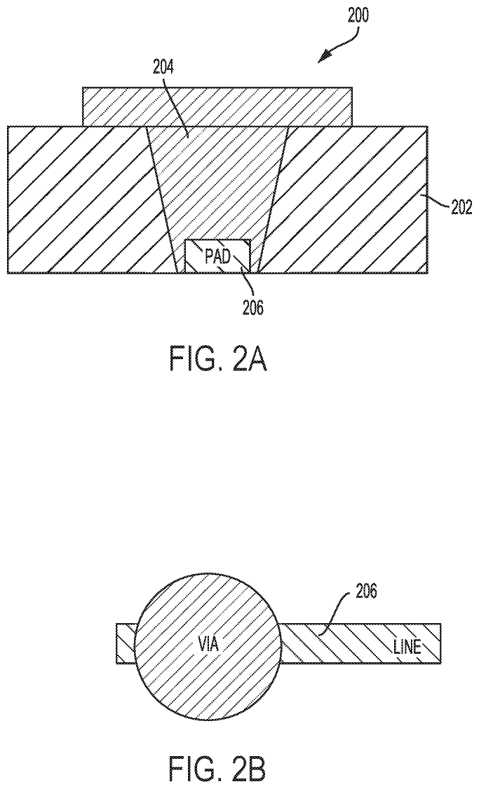

FIG. 2A is a side cross-sectional view illustrating an interconnection structure 200 according to one aspect of the invention. Interconnection structure 200 includes a dielectric 202, a via 204, and a contact pad 206 of the dielectric 202. The contact pad 206 is a, line-shaped pad as shown in FIG. 2B, and formed from a conductive material. The via 204 has a diameter, e.g., of approximately 10-60 microns. The contact pad 206 has a width, e.g., of approximately 2-15 microns. In particular, the width of contact pad 206 is significantly smaller than the width of contact pad 106 as shown in FIGS. 1A and 1B i.e., approximately 2 to 10 times smaller and, as a result, this provides more area in the interconnection structure 200 for routing of I/O signals and design. The contact pad 206 may be formed using photolithography and/or plating processing techniques in locations on the dielectric 202. For example, a controlled laser may be used to drill the via 204 and stop at the contact pad 206 of the dielectric 202. A plasma based process may also be used to drill the via 204. The via 204 may then be cleaned with a wet chemical or plasma etch process to remove any residue.

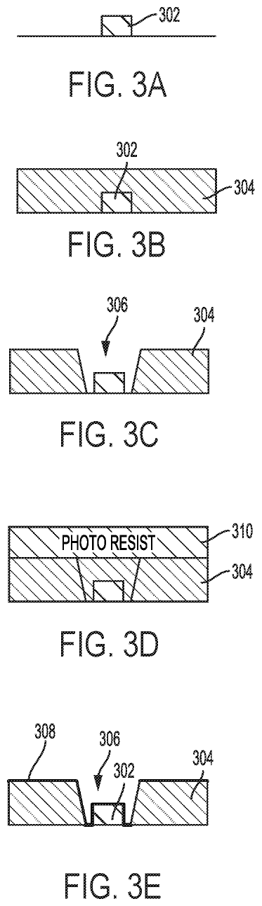

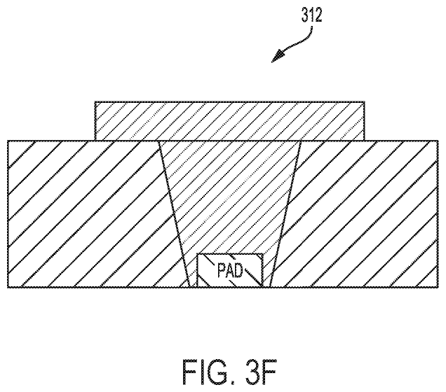

FIGS. 3A-3E illustrate a method of fabricating an interconnection structure having reduced contact pad size according to one aspect of the invention. A photoresist film (not shown) is patterned to expose a contact pad 302 as shown in FIG. 3A. The contact pad 302 has a width, e.g., of approximately 2-15 microns. The photoresist film may have a thickness, e.g., of approximately 10-15 microns. Referring to FIG. 3B, a dielectric layer 304 may be formed, e.g., by lamination, over the contact pad 302. A via opening 306 may then be formed in the dielectric layer 304 as shown in FIG. 3C, the via opening 306 having a first diameter and a second diameter. In one aspect, the via opening 306 may be formed by a photo-exposure process. In another aspect, the via opening 306 may be formed by a laser drilling process through the dielectric layer 304. The laser drilling may be accomplished using a carbon dioxide (CO₂), gas laser beam, an ultraviolet (UV) laser beam, or an excimer laser beam. A photoresist layer 310 may then be developed in a patterning-exposure process as shown in FIG. 3D. The photoresist layer 310 may then be etched as shown in FIG. 3E. After the photoresist layer 310 is etched, top surface(s) of the dielectric layer 304, side surface(s) of the via opening 306, and top and side surface(s) of the contact pad 302 may be filled with a copper (Cu) seed layer 308 as shown in FIG. 3E. This process is also known as copper plating. The copper seed (Cu) layer 308 may then be removed, e.g., by a wet stripping process, and the interconnection structure 312 may be achieved, as shown in FIG. 3F. In another aspect, after the photoresist layer 310 is removed, a flash etch process may be performed to remove the seed (Cu) layer 308 while preserving copper traces in the via opening 306.

In other aspects, the via opening 306 may be formed by an electroless plating process, or the via opening 306 may be formed by vacuum deposit of a metal seed layer, followed by patterning of the photoresist layer 310. In addition, the walls a via opening 306 may be cleaned by plasma cleaning or vapor honing. A feature of the disclosure is the contact pad 302 may be aligned with the via opening 306 resulting in fewer alignment steps. Another feature of the disclosure is the use of laser drilling results in reduced size for the contact pad 302. Yet another feature of the disclosure is there is more area in the dielectric layer 304 for routing of I/O signals and design.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. For instance, a first die may be coupled to a second die in a package even though the first die is never directly physically in contact with the second die.

One or more of the components, steps, features and/or functions illustrated in the figures may be rearranged and/or combined into a single component, step, feature or function or embodied in several components, steps, or functions. Additional elements, components, steps, and/or functions may also be added without departing from novel features disclosed herein. The apparatus, devices, and/or components illustrated in the figures may be configured to perform one or more of the methods, features, or steps described herein. The novel algorithms described herein may also be efficiently implemented in software and/or embedded in hardware.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for.”

1. An interconnect structure, comprising:
a dielectric;
a via formed in the dielectric, the via having a first diameter and a second diameter; and
a contact pad formed in the via and aligned with the second diameter of the via,
wherein the contact pad has a width smaller than the second diameter.

2. The interconnect structure of claim 1, wherein the contact pad is line-shaped.

3. The interconnect structure of claim 1, wherein the second diameter is approximately 2×-10× bigger than the contact pad width.

4. The interconnect structure of claim 1, wherein the width of the contact pad is approximately 2-15 microns.

5. The interconnect structure of claim 1, wherein the first diameter is approximately 10-60 microns.

6. The interconnect structure of claim 1, wherein the via is formed using photolithography, laser ablation, and/or plasma etching.

7-18. (canceled)
